(19) United States
(12) Patent Application Publication
(10) Pub. No.: US 2025/0017076 A1
(43) Pub. Date: Jan. 9, 2025

(54) DISPLAY DEVICE

(71) Applicant: Samsung Display Co., LTD., Yongin-si (KR)

(72) Inventors: Hyun KIM, Yongin-si (KR); Dong Jo KIM, Yongin-si (KR); Seong Geun WON, Yongin-si (KR); Je Won YOO, Yongin-si (KR); Seung Min LEE, Yongin-si (KR); Dan Bi CHOI, Yongin-si (KR); Souk June HWANG, Yongin-si (KR)

(21) Appl. No.: 18/609,315

(22) Filed: Mar. 19, 2024

(30) Foreign Application Priority Data
Jul. 3, 2023 (KR) 10-2023-0085716

(51) Int. Cl. H10K 59/80; H10K 59/90; H10K 102/00

(52) U.S. Cl. CPC H10K 59/80; H10K 59/90; H10K 2102/311

(57) ABSTRACT

A display device includes: a first substrate including: a display area; and a non-display area including a bending area and a pad area; a display element layer on the display area; a bending protective layer on the bending area; a flexible circuit board on the pad area; a circuit protective layer on the pad area, and completely covering the flexible circuit board; a first support member under the display area; and a second support member under the pad area, spaced from the first support member, and including: a first surface in contact with the first substrate; a second surface opposite to the first surface; a first side surface facing the first support member; and a second side surface. The second side surface includes a first inclined surface connected to the second surface, and the first inclined surface of the second support member overlaps with the circuit protective layer.

### CROSS-REFERENCE TO RELATED APPLICATION

The present application claims priority to and the benefit of Korean Patent Application No. 10-2023-0085716, filed on Jul. 3, 2023, in the Korean Intellectual Property Office, the entire disclosure of which is incorporated by reference herein.

### BACKGROUND

### 1. Field

Aspects of embodiments of the present disclosure relate to a display device.

### 2. Description of the Related Art

As information-oriented society evolves, various demands for display devices are ever increasing. Display devices may be flat panel display devices, such as a liquid-crystal display device, a field emission display device, and a light-emitting display device.

A display device includes a display area where images are displayed, and a non-display area around the display area, for example. Recently, the width of the non-display area has been decreasing in order for viewers to get more immersed in the content displayed on the display area, and to increase the aesthetics of the display device.

The above information disclosed in this Background section is for enhancement of understanding of the background of the present disclosure, and therefore, it may contain information that does not constitute prior art.

### SUMMARY

In the process of fabricating a display device, the display device may be formed by cutting a mother substrate along a plurality of display cells formed thereon.

One or more embodiments of the present disclosure are directed to a display device that may prevent or substantially prevent delamination between a display panel and a circuit board, and may prevent or substantially prevent defects in a bending line when a module portion is bent.

One or more embodiments of the present disclosure are directed to a display device that may improve reliability by preventing or substantially preventing a driving failure due to delamination between a display panel and a circuit board, and preventing or substantially preventing defects in a bending line when a module portion is bent.

However, the aspects and features of the present disclosure are not limited to those described above, and other aspects and features of the present disclosure will be apparent to those having ordinary skill in the art from the following descriptions.

According to one or more embodiments of the present disclosure, a reinforcing member may be attached between a display panel and a circuit board, so that it may be possible to prevent or substantially prevent the circuit board from becoming separated when a module portion is bent.

According to one or more embodiments of the present disclosure, a display device includes: a first substrate including: a display area; and a non-display area surrounding the display area, and including a bending area and a pad area; a display element layer on the display area of the first substrate; a bending protective layer on the bending area of the first substrate; a flexible circuit board on the pad area of the first substrate; a circuit protective layer on the pad area of the first substrate, and completely covering the flexible circuit board; a first support member under the display area of the first substrate; and a second support member under the pad area of the first substrate, and spaced from the first support member, the second support member including: a first surface in contact with the first substrate; a second surface opposite to the first surface; a first side surface connecting the first surface to the second surface and facing toward the first support member; and a second side surface opposite to the first side surface. The second side surface includes a first inclined surface connected to the second surface, and the first inclined surface of the second support member overlaps with the circuit protective layer.

In an embodiment, the first surface of the second support member may further include: a first portion overlapping with the bending protective layer; a second portion overlapping with the flexible circuit board and the circuit protective layer; and a third portion overlapping with the circuit protective layer and not overlapping with the flexible circuit board. The third portion of the second support member may be between the first portion and the second portion.

In an embodiment, the first portion and the third portion of the second support member may be spaced from each other.

In an embodiment, the second side surface of the second support member may further include: a second inclined surface connected to the first surface; and a connecting surface connecting the first inclined surface to the second inclined surface. The first inclined surface and the connecting surface may form a first inclination angle therebetween, the second inclined surface and the connecting surface may form a second inclination angle therebetween, and the circuit protective layer may overlap with the second inclined surface and the connection surface.

In an embodiment, the circuit protective layer may include: an adhesive layer in direct contact with the flexible circuit board; and a protective layer on the adhesive layer.

In an embodiment, the first support member and the second support member may include glass and a plastic, and a thickness of the first support member and the second support member may be equal to or less than 200 μm.

In an embodiment, the first side surface of the second support member may further include: a third inclined surface connected to the second surface; and a fourth inclined surface connected to the third inclined surface and the first surface. The bending protective layer may overlap with the third inclined surface and the fourth inclined surface.

In an embodiment, the display device may further include a display driver circuit on the flexible circuit board. The circuit protective layer may be in contact with the display driver circuit, and the circuit protective layer may completely cover the display driver circuit.

In an embodiment, the display device may further include a main circuit board spaced from the first substrate, and connected to the first substrate by the flexible circuit board. The circuit protective layer may be in contact with the main circuit board, and may partially cover the main circuit board.

In an embodiment, the circuit protective layer may include an alignment mark in a plan view. The alignment mark may overlap with the pad area, and may be located at each of two corners of the circuit protective layer.

In an embodiment, the circuit protective layer may include an alignment hole in a plan view. The alignment hole may overlap with the pad area, and may be located at each of two corners of the circuit protective layer.

In an embodiment, the circuit protective layer may overlap with the display element layer when the first substrate is bent.

In an embodiment, the display device may further include a subsidiary circuit protective layer under the pad area of the first substrate. The subsidiary circuit protective layer may be in contact with a lower portion of the second support member, and the subsidiary circuit protective layer may overlap with the first inclined surface of the second support member.

In an embodiment, a width of the subsidiary circuit protective layer in a first direction may be greater than a width of the flexible circuit board in the first direction.

In an embodiment, the display device may further include a vacant area between the flexible circuit board and the subsidiary circuit protective layer, and the vacant area may be surrounded by the second support member, the first substrate, the flexible circuit board, and the subsidiary circuit protective layer.

In an embodiment, the display device may further include a main circuit board spaced from the first substrate, and connected to the first substrate by the flexible circuit board. The subsidiary circuit protective layer may be in contact with the main circuit board, and may partially cover the main circuit board.

In an embodiment, the subsidiary circuit protective layer may overlap with the display element layer when the first substrate is bent.

In an embodiment, the display device may further include a display driver circuit between the bending protective layer and the circuit protective layer, and the display driver circuit may be spaced from the bending protective layer and the circuit protective layer.

In an embodiment, the display device may further include a display driver circuit on the pad area of the first substrate, and spaced from the bending protective layer and the circuit protective layer therebetween. The circuit protective layer may completely cover the display driver circuit and the flexible circuit board.

According to one or more embodiments of the present disclosure, a display device includes: a first substrate including: a display area; and a non-display area surrounding the display area, and including a bending area and a pad area; a display element layer on the display area of the first substrate; a bending protective layer on the bending area of the first substrate; a flexible circuit board on the pad area of the first substrate; a first support member under the display area of the first substrate; a second support member under the pad area of the first substrate, and spaced from the first support member; and a subsidiary circuit protective layer under the pad area of the first substrate, and in contact with the second support member under the second support member. The second support member includes: a first surface in contact with the first substrate; a second surface opposite to the first surface; a first side surface connecting the first surface to the second surface, and facing toward the first support member; and a second side surface opposite to the first side surface. The second side surface includes a first inclined surface connected to the second surface, and the first inclined surface of the second support member overlaps with the subsidiary circuit protective layer.

According to one or more embodiments of the present disclosure, a reinforcing member may be attached between a display panel and a circuit board, so that it may be possible to improve reliability, and prevent or substantially prevent a driving failure that may occur when a module portion is bent.

However, the aspects and features of the present disclosure are not limited to those described above, and other aspects and features of the present disclosure will be more apparent to those having ordinary skill in the art from the following descriptions with reference to the drawings.

### BRIEF DESCRIPTION OF THE DRAWINGS

The above and other aspects and features of the present disclosure will be more clearly understood from the following detailed description of the illustrative, non-limiting embodiments with reference to the accompanying drawings, in which:

FIG. 1 is a plan view showing a display device according to an embodiment of the present disclosure.

FIG. 2 is a perspective view showing the display device of FIG. 1 with the subsidiary area in a bent state.

FIG. 3 is a plan view showing a display device including a circuit board attached thereto according to an embodiment of the present disclosure.

FIG. 4 is a cross-sectional view of the display device taken along the line X1-X1′ of FIG. 3.

FIG. 5 is an enlarged cross-sectional view of the area A of FIG. 4.

FIG. 6 is a cross-sectional view of the display device of FIG. 4 in a bent state.

FIG. 7 is an enlarged cross-sectional view of the area A of FIG. 4.

FIG. 8 is a cross-sectional view of the display device taken along the line X1-X1′ of FIG. 3.

FIG. 9 is an enlarged cross-sectional view of the area C of FIG. 8.

FIG. 10 is a cross-sectional view of the display device taken along the line X1-X1′ of FIG. 3.

FIG. 11 is an enlarged cross-sectional view of the area E of FIG. 10.

FIG. 12 is a cross-sectional view of the display device taken along the line X1-X1′ of FIG. 3.

FIG. 13 is a cross-sectional view of the display device taken along the line X1-X1′ of FIG. 3.

FIG. 14 is a cross-sectional view of the display device taken along the line X1-X1′ of FIG. 3.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

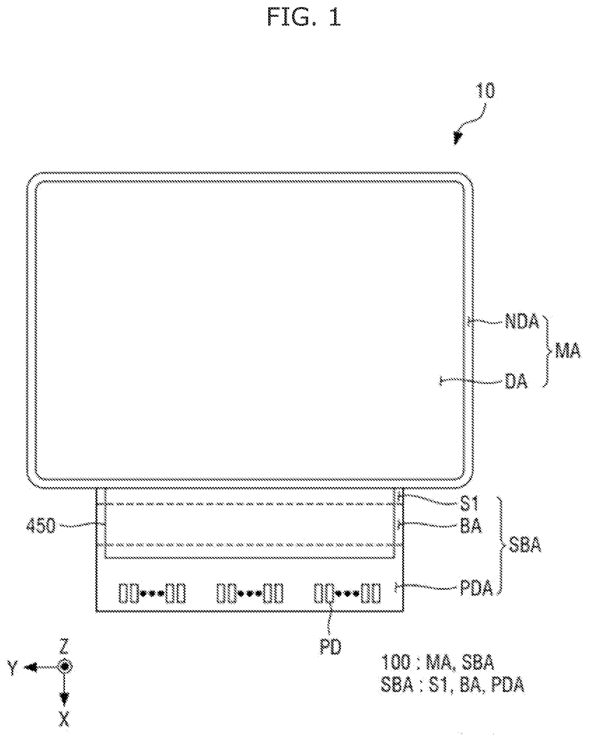

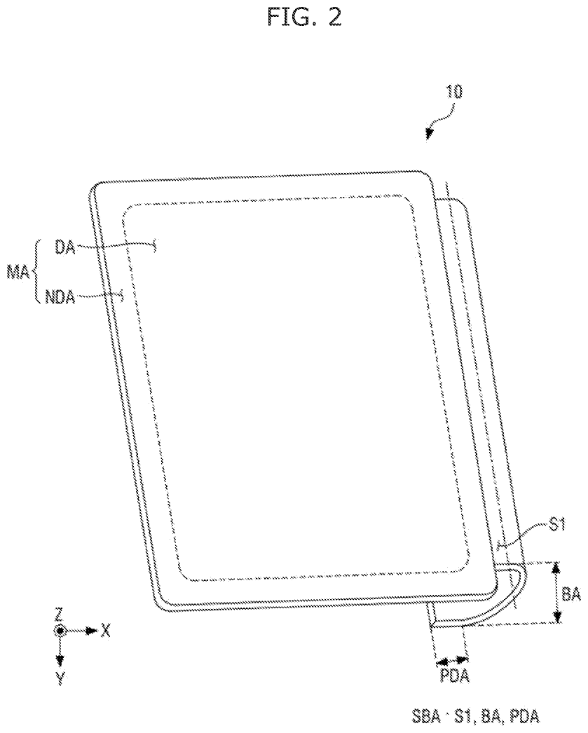

FIG. 1 is a plan view showing a display device according to an embodiment of the present disclosure. FIG. 2 is a perspective view showing the display device of FIG. 1 with a subsidiary area SBA in a bent state.

Referring to FIGS. 1 and 2, a display device 10 is a device for displaying moving images and/or still images. The display device 10 may be used as the display screen of various suitable portable electronic devices, such as a mobile phone, a smart phone, a tablet PC, a smart watch, a watch phone, a mobile communications terminal, an electronic notebook, an electronic book, a portable multimedia player (PMP), a navigation device, and a ultra mobile PC (UMPC), as well as the display screen of various suitable products, such as a television, a notebook, a monitor, a billboard, and an Internet of Things (IoT) device.

The display device 10 may be a light-emitting display device, such as an organic light-emitting display device that uses organic light-emitting diodes, an inorganic light-emitting display device including an inorganic semiconductor, and a micro light-emitting display device that uses micro or nano light-emitting diodes (micro LEDs or nano LEDs). Hereinafter, for convenience, the organic light-emitting display device may be described in more detail as a representative example of the display device 10. However, the present disclosure is not limited thereto.

The display device 10 may include a display panel 100, display pads PD, and a bending protective layer 450.

The display panel 100 may include a main area MA and the subsidiary area SBA.

The main area MA may include a display area DA where images are displayed, and a non-display area NDA around (e.g., adjacent to) the display area DA.

The main area MA of the display panel 100 may be formed in a rectangular plane shape having shorter sides extending in a first direction (e.g., the X-axis direction) X, and longer sides extending in a second direction (e.g., the Y-axis direction) Y crossing or intersecting the first direction (e.g., the X-axis direction) X. Each of the corners where a corresponding shorter side extending in the first direction X meets a corresponding longer side extending in the second direction Y may be rounded with a suitable curvature (e.g., a predetermined curvature), or may be a right angle. The shape of the display panel 100 when viewed from the top (e.g., in a plan view) is not limited to a quadrangular shape, and may be formed in a different polygonal shape, a circular shape, or an elliptical shape. The display panel 100 may be formed to be flat or substantially flat, but the present disclosure is not limited thereto. For example, the display panel 100 may be formed at left and right ends, and may include a curved portion having a constant or substantially constant curvature or a varying curvature. In addition, the display panel 100 may be flexible, so that it can be curved, bent, folded, or rolled.

The display area DA may occupy most of the main area MA, and may be disposed in the center of the main area MA. In the display area DA, pixels may be disposed to display images. Each of the pixels may include a plurality of emission areas.

The non-display area NDA may be disposed adjacent to the display area DA. The non-display area NDA may be disposed on the outer side of the display area DA. The non-display area NDA may surround (e.g., around a periphery of) the display area DA. The non-display area NDA may be defined as the border of the display panel 100.

The subsidiary area SBA may protrude from one side of the main area MA in the first direction X. The length of the subsidiary area SBA in the first direction X may be smaller than the length of the main area MA in the first direction X. The length of the subsidiary area SBA in the second direction Y may be smaller than the length of the main area MA in the second direction Y as shown in FIG. 1, but the present disclosure is not limited thereto. For example, the length of the subsidiary area SBA in the second direction Y may be smaller than or equal to or substantially equal to the length of the main area MA in the second direction Y.

The subsidiary area SBA may include a first subsidiary area S1, a bending area BA, and a pad area PDA. The first subsidiary area S1, the bending area BA, and the pad area PDA may be arranged along the first direction X.

The first subsidiary area S1 may protrude from one side of the main area MA in the first direction X. One side of the first subsidiary area S1 may be in contact with the non-display area NDA of the main area MA, and an opposite side of the first subsidiary area S1 may be in contact with the bending area BA. As shown in FIG. 1, the first subsidiary area S1 may be connected to the main area MA at a right angle, but the present disclosure is not limited thereto. The first subsidiary area S1 may be connected to the main area MA in a curved shape.

The bending area BA may be bendable, and may be located between the first subsidiary area S1 and the pad area PDA. As shown in FIG. 2, the subsidiary area SBA may be bent by the bending area BA, and the bent subsidiary area SBA may be located on the rear surface of the display panel 100. The bent pad area PDA may overlap with the main area MA in a third direction (e.g., the Z-axis direction) Z.

The bending protective layer 450 may be positioned to overlap with the subsidiary area SBA. In more detail, the bending protective layer 450 may entirely or substantially entirely overlap with the first subsidiary area S1 and the bending area BA, and may overlap with a part of the pad area PDA.

The bending protective layer 450 may protect a variety of lines disposed in the bending area BA from moisture and oxygen. When viewed from the top (e.g., in a plan view), the width of the bending protective layer 450 in the second direction Y may be smaller than or equal to the width of the display panel 100.

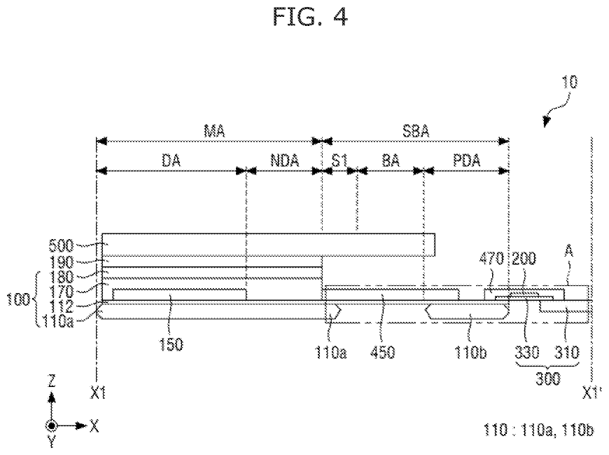

In the pad area PDA, the display pads PD may be disposed. A plurality of the display pads PD may be disposed at an edge of the subsidiary area SBA, and may be electrically connected to the display device 10 by an adhesive member. The plurality of display pads PD may provide data signals and control signals for driving the pixels to a display element layer 150 (e.g., see FIG. 4).

The length of the plurality of display pads PD in the first direction X may be greater than the length thereof in the second direction Y. For example, when viewed from the top (e.g., in a plan view), the display pads PD may have, but is not limited to, a shape of a rectangle, a parallelogram, or stripes extended in a direction.

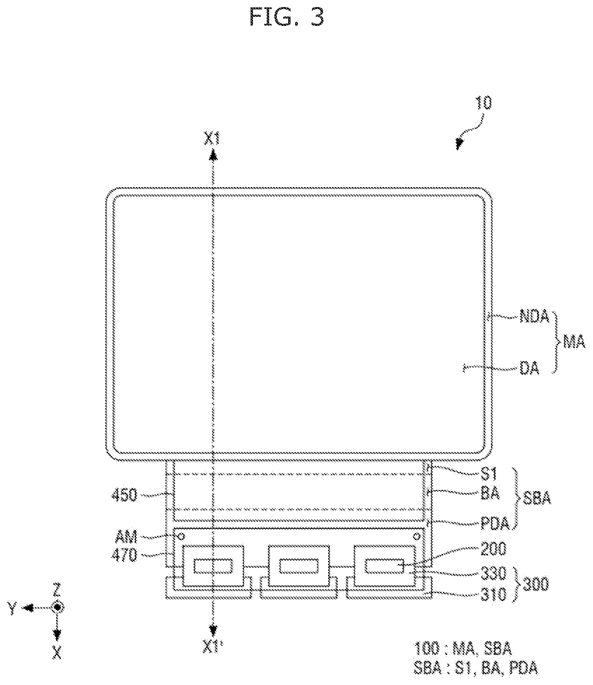

FIG. 3 is a plan view showing a display device including a circuit board attached thereto according to an embodiment of the present disclosure.

Referring to FIG. 3, the circuit board 300 may be attached to one end of the subsidiary area SBA of the display panel 100. The circuit board 300 may include main circuit boards 310 and flexible circuit boards 330.

Display driver circuits 200 may be located on the circuit board 300, and may be connected to the flexible circuit boards 330 to operate by a chip-on-film (COF) technology. However, that the present disclosure is not limited thereto. The display driver circuits 200 may be mounted by a chip-on-glass (COG) technology or a chip-on-plastic (COP) technology. The display driver circuits 200 may provide electrical signals for driving a plurality of the pixels to the display panel 100, and may also provide touch signals for recognizing a user's touch input, a fingerprint pattern, and a pen input.

The flexible circuit boards 330 may electrically connect the display panel 100 to the main circuit boards 310. One side of each of the flexible circuit boards 330 in the first direction X may be attached to the pad area PDA of the display panel 100, and an opposite side of each of the flexible circuit boards 330 in the first direction X may be attached to at least one of the main circuit boards 310. The flexible circuit boards 330 may have a flexibility to be bent. For example, the flexible circuit boards 330 may be flexible circuit films.

The main circuit board 310 may be connected to the flexible circuit board 330. The main circuit board 310 may be electrically connected to the display panel 100 by the flexible circuit board 330.

A circuit protective layer 470 may overlap with the pad area PDA of the display panel 100. In addition, the circuit protective layer 470 may cover a part of the main circuit boards 310 that are spaced apart from the display panel 100. In other words, the circuit protective layer 470 may cover a part of the display panel 100, and may extend to cover a part of the main circuit boards 310. Accordingly, the circuit protective layer 470 may completely cover the flexible circuit boards 330.

In some embodiments, the circuit protective layer 470 may not overlap with the bending protective layer 450, and may be spaced apart from the bending protective layer 450 in the first direction X. The width of the circuit protective layer 470 in the second direction Y may be equal to or smaller than the width of the display panel 100.

The circuit protective layer 470 may protect the display panel 100 and the flexible circuit board 330 from being detached from each other when the subsidiary area SBA is bent by the bending area BA. In addition, it may be possible to prevent or substantially prevent a defect in which an additional line that is not designed is created when the subsidiary area SBA of the display panel 100 is bent.

In some embodiments, the circuit protective layer 470 may include alignment marks AM, and may be visually aligned with alignment marks formed on the display panel 100. The alignment marks AM of the circuit protective layer 470 may be located at both corners (e.g., opposite corners) on a side closer to the bending protective layer 450 in the pad area PDA of the display panel 100. FIG. 3 shows the alignment marks AM having a circular shape, but the present disclosure is not limited thereto. For example, the alignment marks AM may be formed in various suitable shapes, such as a rectangle, a pentagon, a hexagon, a triangle, and a diamond.

In addition, the alignment marks AM of the circuit protective layer 470 may be formed as a hole. The alignment marks AM of the circuit protective layer 470 may include any suitable shape, as long as it may be used for aligning the underlying display panel 100 with the circuit protective layer 470.

FIG. 4 is a cross-sectional view of the display device 10 taken along the line X1-X1′ of FIG. 3.

Referring to FIG. 4, the display device 10 may include the display panel 100, a polarizing film 190, and a cover window 500. The display panel 100 may include a first substrate 110, a second substrate 112, a display element layer 150, a thin-film encapsulation layer 170, a touch sensor layer 180, and the bending protective layer 450.

The first substrate 110 may include a rigid material that may transmit light. For example, the first substrate 110 may be a glass substrate or a plastic substrate. The first substrate 110 may be formed of ultra thin glass (UTG) having a thickness of 200 μm or less.

In some embodiments, the first substrate 110 may be partially etched to form the bending area BA and to support the second substrate 112. Accordingly, the first substrate 110 may be divided into a first subsidiary substrate 110a and a second subsidiary substrate 110b.

The first subsidiary substrate 110a of the first substrate 110 may overlap with the main area MA and the first subsidiary area S1 of the subsidiary area SBA. The second subsidiary substrate 110b of the first substrate 110 may overlap with the pad area PDA of the subsidiary area SBA. The first subsidiary substrate 110a and the second subsidiary substrate 110b may be spaced apart from each other to expose the bending area BA. Accordingly, the first substrate 110 may ensure the bending area BA of the display panel 100.

The second substrate 112 may include (e.g., may be made of) a polymer resin having a flexible material. For example, the second substrate 112 may have a thickness of approximately 20 μm. The second substrate 112 may be formed of an organic material, such as an acryl resin, an epoxy resin, a phenolic resin, a polyamide resin, and/or a polyimide resin.

The display element layer 150 may be disposed on the second substrate 112 to overlap with the display area DA of the main area MA. The display element layer 150 may be a layer that displays images. The display element layer 150 may include an emissive layer that emits light, and a plurality of signal lines.

The thin-film encapsulation layer 170 may be disposed over the display element layer 150 in the main area MA. The thin-film encapsulation layer 170 may include at least one inorganic film to prevent or substantially prevent permeation of oxygen and/or moisture into the display element layer 150. In addition, the thin-film encapsulation layer 170 may include at least one organic film to protect the display element layer 150 from particles, such as dust.

The touch sensor layer 180 may be disposed on the thin-film encapsulation layer 170 in the main area MA. The touch sensor layer 180 may include sensor electrodes. The touch sensor layer 180 may sense a user's touch using the sensor electrodes.

The polarizing film 190 may be disposed on the display panel 100 in order to reduce a reflection of external light. The polarizing film 190 may include a first base member, a linear polarizer, a retardation film such as a λ/4 (quarter-wave) plate, and a second base member. The first base member, the retardation film, the linear polarizer, and the second base member of the polarizing film 190 may be sequentially stacked on the display panel 100.

The cover window 500 may be disposed on the polarizing film 190. The cover window 500 may be attached onto the polarizing film 190 by a transparent adhesive member, such as an optically clear adhesive (OCA) film.

The bending protective layer 450 may be disposed on the second substrate 112 in the subsidiary area SBA. The bending protective layer 450 may be disposed on the first subsidiary substrate 110a and the second subsidiary substrate 110b of the first substrate 110, and may overlap with the first subsidiary substrate 110a and the second subsidiary substrate 110b in the third direction Z.

The bending protective layer 450 may include a synthetic resin. For example, the bending protective layer 450 may include at least one of acrylonitrile butadiene styrene copolymer (ABS), urethane acrylate (UA), polyurethane (PU), polyethylene (PE), ethylene vinyl acetate (EVA), and/or polyvinyl chloride (PVC).

When the substrate 112 is bent, the bending protective layer 450 may adjust the underlying lines disposed in the bending area BA, so that they are positioned close to a neutral plane. In this manner, the bending protective layer 450 may relieve a compressive stress that the underlying lines may receive.

The circuit protective layer 470 may be spaced apart from the bending protective layer 450, and may completely cover the flexible circuit boards 330 and the display driver circuits 200. In addition, the circuit protective layer 470 may cover a part of the main circuit boards 310. In other words, the circuit protective layer 470 may cover a part of the display panel 100, and may be extended to cover a part of the main circuit boards 310 that are spaced apart from the display panel 100.

In some embodiments, the circuit protective layer 470 may be transparent, rigid, adhesive, and non-conductive. For example, the circuit protective layer 470 may be, but is not limited to, a PET film. For example, the circuit protective layer 470 may include all of graphite, acrylic, silicone, and epoxy films, and the thickness thereof may vary depending on the characteristics of each film. For example, the thickness of the circuit protective layer 470 in the third direction Z may be equal to or greater than 0.1 T.

The circuit protective layer 470 may protect the circuit board 300 from defects that may be caused when the subsidiary area SBA is bent. The circuit protective layer 470 may prevent or substantially prevent delamination and cracking of the flexible circuit boards 330 when the subsidiary area SBA is bent. In addition, the circuit protective layer 470 may prevent or substantially prevent a defect that may create an additional line other than the designed bending lines on the display panel 100.

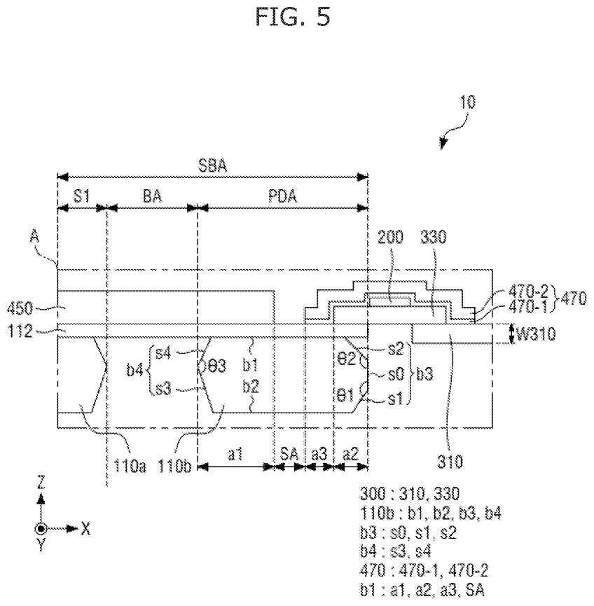

FIG. 5 is an enlarged cross-sectional view of the area A of FIG. 4.

Referring to FIG. 5, the second subsidiary substrate 110b may include a first surface b1 in contact with the second substrate 112, a second surface b2 opposite to the first surface b1, a first side surface b3 facing the main circuit boards 310, and a second side surface b4 facing the first subsidiary substrate 110a.

In some embodiments, the first substrate 110 may undergo a grinding process during the fabrication processes. For example, the grinding process may be for grinding edges of a substrate. Therefore, the first side surface b3 of the second subsidiary substrate 110b may include a first inclined surface s1 connected to the second surface b2, a second inclined surface s2 connected to the first surface b1, and a connecting surface s0 connecting the first inclined surface s1 to the second inclined surface s2. For example, because the second subsidiary substrate 110b includes the first inclined surface s1 and the second inclined surface s2, it can be seen that the first substrate 110 undergoes a grinding process during the fabrication processes.

In some embodiments, the first inclined surface s1 and the connecting surface s0 may form a first inclination angle θ1 therebetween, and the second inclined surface s2 and the connecting surface s0 may form a second inclination angle θ2 therebetween. The first inclination angle θ1 and the second inclination angle θ2 may or may not be equal to each other depending on the fabrication processes.

During the fabrication processes, the second subsidiary substrate 110b may overlap with the bending area BA, and may undergo an etching process. Accordingly, the second side surface b4 of the second subsidiary substrate 110b may include a third inclined surface s3 connected to the second surface b2, and a fourth inclined surface s4 connected to the first surface b1. The third inclined surface s3 and the fourth inclined surface s4 may form a third angle θ3 therebetween. For example, because the second subsidiary substrate 110b includes the third inclined surface s3 and the fourth inclined surface s4, it can be seen that the bending area BA of the first substrate 110 undergoes an etching process.

In some embodiments, the first surface b1 of the second subsidiary substrate 110b may include a first portion a1 overlapping with the bending protective layer 450, a second portion a2 overlapping with the circuit protective layer 470 and the flexible circuit boards 330, and a third portion a3 overlapping with the circuit protective layer 470 but not overlapping with the flexible circuit boards 330. The third portion a3 overlapping with the circuit protective layer 470 but not overlapping with the flexible circuit boards 330 may be spaced apart from the first portion a1 overlapping with the bending protective layer 450. Accordingly, there may be a spaced area SA between the third portion a3 and the first portion a1, and the spaced area SA may be exposed (e.g., may overlap with an area) between the bending protective layer 450 and the circuit protective layer 470 in a plan view.

Although the second subsidiary substrate 110b of the first substrate 110 has been described in more detail, the first subsidiary substrate 110a of the first substrate 110 may include the same or substantially the same structure as that of the second subsidiary substrate 110b of the first substrate 110. For example, the first subsidiary substrate 110a of the first substrate 110 may include an upper surface in contact with the second substrate 112, a lower surface, and opposite side surfaces. The first subsidiary substrate 110a may include a third inclined surface s3 and a fourth inclined surface s4 facing toward the second subsidiary substrate 110b, which may result from the etching process, and may include a first inclined surface s1 and a second inclined surface s2 on an opposite side, which may result from the grinding process.

The flexible circuit boards 330 may be disposed on the second subsidiary substrate 110b of the first substrate 110. One sides of the flexible circuit boards 330 in the first direction X may be positioned on the main circuit boards 310, and the opposite sides in the first direction X may be positioned on the second substrate 112. For example, in the cross-sectional view, the flexible circuit boards 330 may be disposed on a part of the second substrate 112 that overlaps the second portion a2 of the second subsidiary substrate 110b.

In the cross-sectional view, the circuit protective layer 470 may be positioned on a part of the second substrate 112 that overlaps with the second and third portions a2 and a3 of the second subsidiary substrate 110b. In other words, the circuit protective layer 470 may overlap with the second inclined surface s2 and the first inclined surface s1 of the second subsidiary substrate 110b.

In some embodiments, the circuit protective layer 470 may include a first surface 470-1 including an adhesive surface, and a second surface 470-2 including a protection feature. The first surface 470-1 of the circuit protective layer 470 may be disposed to be in direct contact with the flexible circuit boards 330 and the display driver circuits 200.

The circuit protective layer 470 may be extended from the pad area PDA of the display panel 100 to cover a part of the main circuit boards 310 that are spaced apart from the display panel 100. Accordingly, the circuit protective layer 470 may be positioned to completely cover the flexible circuit boards 330 and the display driver circuits 200.

A thickness W310 of the main circuit boards 310 in the third direction Z may be smaller than the thickness of the first substrate 110 as shown in FIG. 5, but the present disclosure is not limited thereto. The thickness W310 of the main circuit boards 310 in the third direction Z may be variously modified as needed or desired, and may be equal to or smaller than the thickness of the first substrate 110.

The bending protective layer 450 may be positioned on a part of the second substrate 112 that overlaps with the first portion a1 of the second subsidiary substrate 110b. In other words, the bending protective layer 450 may overlap with the third inclined surface s3 and the fourth inclined surface s4 of the second subsidiary substrate 110b.

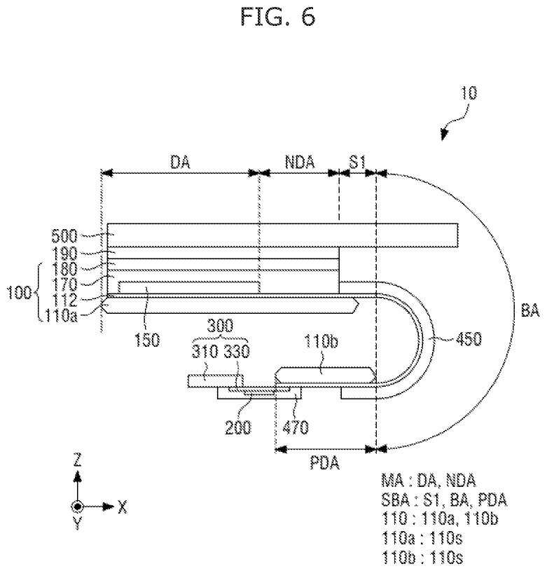

FIG. 6 is a cross-sectional view of the display device 10 of FIG. 4 in a bent state.

Referring to FIG. 6, the subsidiary area SBA of the display device 10 may be bent by the bending area BA. When the subsidiary area SBA is bent, the first subsidiary substrate 110a of the first substrate 110 may overlap with the main area MA, the first subsidiary area S1 of the subsidiary area SBA, and the pad area PDA, and the second subsidiary substrate 110b of the first substrate 110 may overlap with the non-display area NDA of the main area MA, the first subsidiary area S1 of the subsidiary area SBA, and the pad area PDA.

When the subsidiary area SBA is bent, the circuit protective layer 470 may be located in the main area MA and the pad area PDA of the subsidiary area SBA. In other words, when the subsidiary area SBA is bent, the circuit protective layer 470 may overlap with the display element layer 150 included in the main area MA.

As described above, when the subsidiary area SBA is bent, the circuit protective layer 470 may prevent or substantially prevent the flexible circuit boards 330 from being separated from the second substrate 112 and cracking.

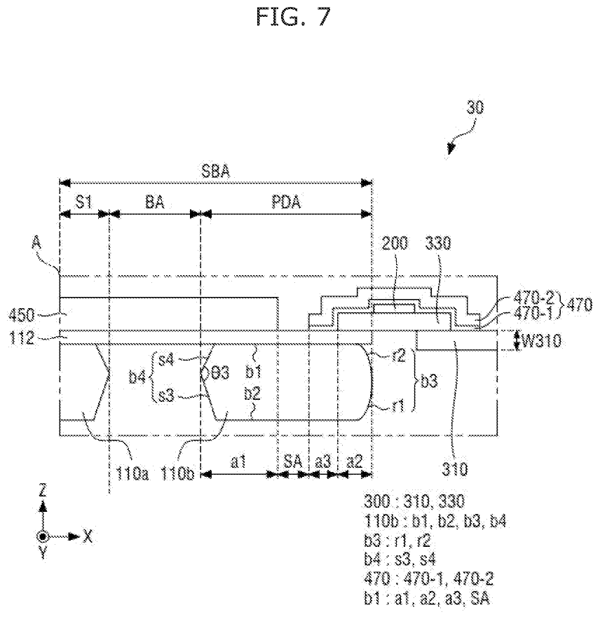

FIG. 7 is an enlarged cross-sectional view of the area A of FIG. 4.

Referring to FIG. 7, the first substrate 110 of the display device 30 may undergo a laser etching during the fabrication processes. Accordingly, unlike that described above with reference to FIG. 5, a first side surface b3 of the second subsidiary substrate 110b illustrated in FIG. 7 includes a first rounded surface r1 and a second rounded surface r2. In more detail, the circuit protective layer 470 of the display device 30 may overlap with the first rounded surface r1 and the second rounded surface r2 of the second subsidiary substrate 110b.

For example, because the first side surface b3 of the second subsidiary substrate 110b includes the first rounded surface r1 and the second rounded surface r2, it can be seen that the display device 30 undergoes a laser etching process during the fabrication processes. The other elements illustrated in FIG. 7 may be the same or substantially the same as those described above, and thus, redundant description thereof may not be repeated.

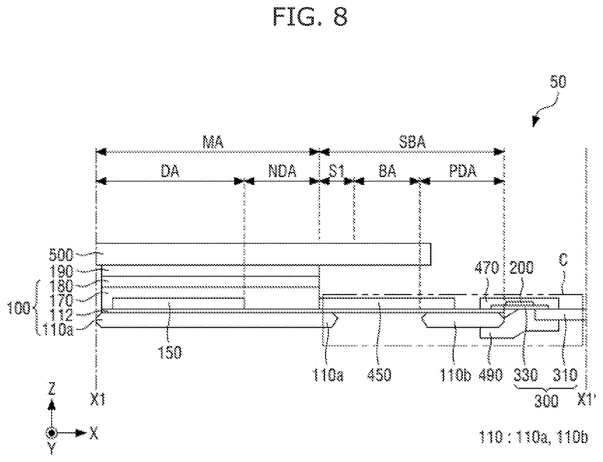

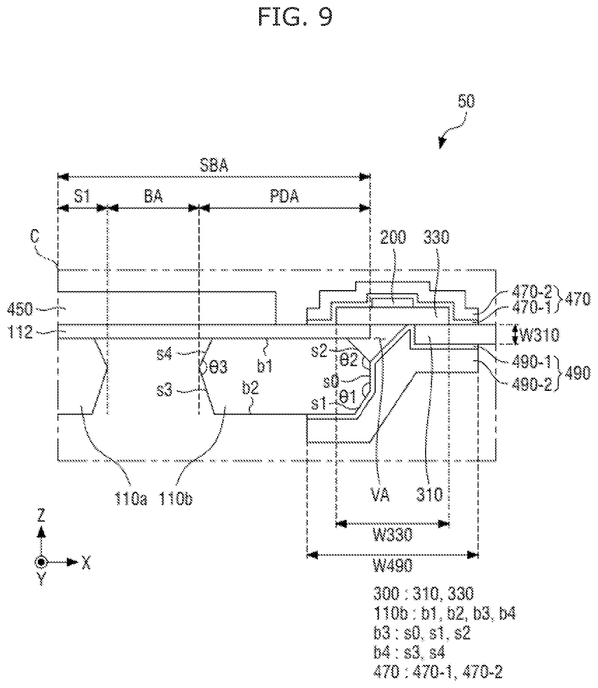

FIG. 8 is a cross-sectional view of a display device 50 taken along the line X1-X1′ of FIG. 3. FIG. 9 is an enlarged cross-sectional view of the area C of FIG. 8.

Referring to FIGS. 8 and 9, the display device 50 further includes a subsidiary circuit protective layer 490 overlapping with the circuit protective layer 470. The subsidiary circuit protective layer 490 may be located on the lower surface of the first substrate 110, and may be in contact with the second subsidiary substrate 110b.

In some embodiments, a width W490 of the subsidiary circuit protective layer 490 in the first direction X may be greater than a width W330 of the flexible circuit boards 330. Accordingly, the subsidiary circuit protective layer 490 may cover a part of the second subsidiary substrate 110b, and a part of the main circuit boards 310 with a width larger than that of the flexible circuit boards 330.

The subsidiary circuit protective layer 490 may overlap with the first side surface b3 of the second subsidiary substrate 110b. Accordingly, the subsidiary circuit protective layer 490 may overlap with the first and second inclined surfaces s1 and s2 of the second subsidiary substrate 110b.

The subsidiary circuit protective layer 490 may prevent or substantially prevent a defect that may create an additional bending line on the display panel 100 in addition to the designed ones, and may prevent or substantially prevent physical line marks that may occur in the opposite direction to the bending direction. In other words, the reliability of the display device 50 may be improved.

However, the present disclosure is not limited to both the circuit protective layer 470 and the subsidiary circuit protective layer 490 being disposed as illustrated in FIGS. 8 and 9. For example, the display device 50 may not include the circuit protective layer 470, and may include the subsidiary circuit protective layer 490 under the second substrate 112. However, it should be noted that when both the circuit protective layer 470 and the subsidiary circuit protective layer 490 are positioned to overlap with the flexible circuit boards 330 on both sides, respectively, the protection of the flexible circuit boards 330 of the display device 50 may be improved (e.g., may be more reliably provided).

In some embodiments, the subsidiary circuit protective layer 490 may include a first surface 490-1 that is an adhesive, and a second surface 490-2 including a protection feature. The subsidiary circuit protective layer 490 may be in contact with the second subsidiary substrate 110b and the main circuit boards 310, to cover them with a width larger than that of the flexible circuit boards 330.

In some embodiments, in the display device 50, there may be a vacant area VA between the flexible circuit boards 330 and the subsidiary circuit protective layer 490. The subsidiary circuit protective layer 490 may include (e.g., may be made of) the same material as that of the circuit protective layer 470, and thus, may have the same or substantially the same physical properties. For example, the subsidiary circuit protective layer 490 may be transparent, highly rigid, and adhesive. Therefore, the subsidiary circuit protective layer 490 may not cover a part of the second subsidiary substrate 110b and the main circuit boards 310, and may include the vacant area VA.

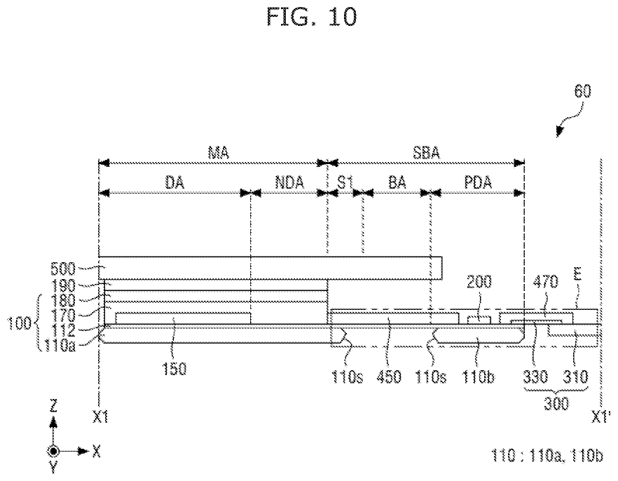

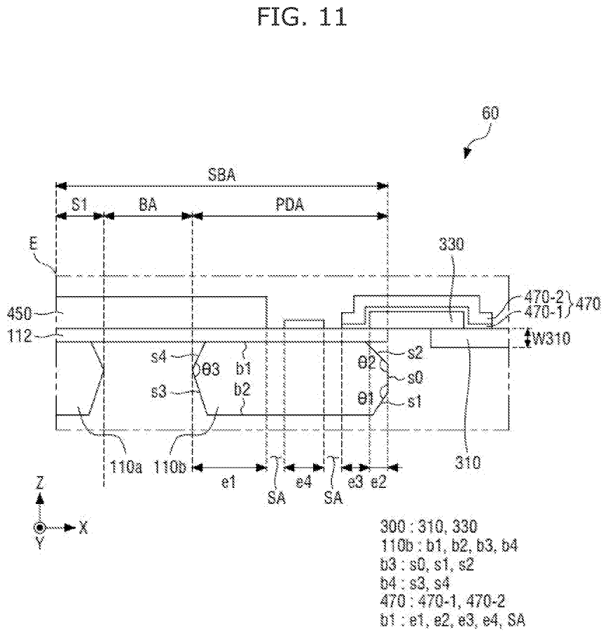

FIG. 10 is a cross-sectional view of a display device 60 taken along the line X1-X1′ of FIG. 3. FIG. 11 is an enlarged cross-sectional view of the area E of FIG. 10.

Referring to FIG. 10, the display device 60 may be different from those described above, in that the display driver circuits 200 are located separately from the circuit board 300. The display driver circuits 200 may be positioned between the bending protective layer 450 and the circuit protective layer 470 on the second subsidiary substrate 110b. The display driver circuits 200 may be disposed on the second substrate 112, and may be electrically connected to the flexible circuit boards 330 by a chip-on glass (COG) technology.

In some embodiments, the circuit protective layer 470 may be spaced apart from the display driver circuits 200 in the first direction X, and may completely cover the flexible circuit boards 330. In other words, the circuit protective layer 470 of the display device 60 may not cover the display driver circuits 200.

Referring to FIG. 11, a first surface b1 of the second subsidiary substrate 110b included in the display device 60 may include a first portion e1 overlapping with the bending protective layer 450, a second portion e2 overlapping with the flexible circuit boards 330 and the circuit protective layer 470, a third portion e3 overlapping with the circuit protective layer 470 but not overlapping with the flexible circuit boards 330, and a fourth portion e4 overlapping with the display driver circuits 200. Spaced areas SA may be located between the first portion e1 overlapping with the bending protective layer 450 and the fourth portion e4 overlapping with the display driver circuits 200, and between the third portion e3 overlapping with the circuit protective layer 470 and the fourth portion e4 overlapping with the display driver circuits 200. The spaced areas SA may be exposed to the outside of the display device 60. The second portion e2 overlapping with the flexible circuit boards 330 and the circuit protective layer 470 may be connected to the third portion e3 overlapping with the circuit protective layer 470.

The flexible circuit boards 330 may be disposed on the second subsidiary substrate 110b of the first substrate 110. One sides of the flexible circuit boards 330 in the first direction X may be attached to the main circuit boards 310, and the opposite sides in the first direction X may be attached to the second substrate 112. For example, the flexible circuit boards 330 may be in contact with a part of the second substrate 112 that overlaps with the second portion e2 of the second subsidiary substrate 110b.

The circuit protective layer 470 may be positioned over a part of the second substrate 112 overlapping with the second portion e2 and the third portion e3 of the second subsidiary substrate 110b, and may be in contact with the second substrate 112 overlapping with the third portion e3 of the second subsidiary substrate 110b. The circuit protective layer 470 may overlap with the second inclined surface s2 and the third inclined surface s3 of the second subsidiary substrate 110b. The other elements illustrated in FIGS. 10 and 11 may be the same or substantially the same as those described above, and thus, redundant description thereof may not be repeated.

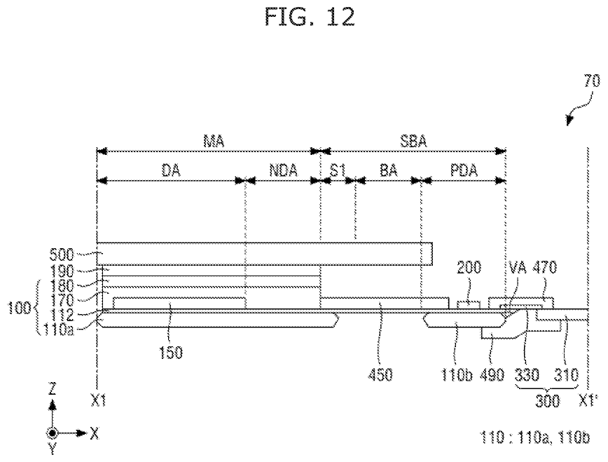

FIGS. 12 through 14 are cross-sectional views of display devices taken along the line X1-X1′ of FIG. 3.

Referring to FIG. 12, a display device 70 may be different from the display device 60 described above, in that the display device 70 further includes a subsidiary circuit protective layer 490 covering the flexible circuit boards 330 on the opposite side from the circuit protective layer 470. In addition, the display device 70 may be different from the display device 50 described above, in that the subsidiary circuit protection layer 490 may not overlap with the display driver circuits 200.

The subsidiary circuit protective layer 490 may be positioned under the first substrate 110. In addition, the subsidiary circuit protective layer 490 may be disposed to be in contact with the second subsidiary substrate 110b. The subsidiary circuit protective layer 490 may have a greater width than that of the flexible circuit boards 330 in the first direction X. The subsidiary circuit protective layer 490 may be positioned to cover a part of the second subsidiary substrate 110b and a part of the main circuit boards 310.

Although the circuit protective layer 470 and the subsidiary circuit protective layer 490 are both disposed in FIG. 12, the present disclosure is not limited thereto. For example, the display device 70 may not include the circuit protective layer 470, and may include the subsidiary circuit protective layer 490 under the second substrate 112. However, it should be noted that when the display device 70 includes both the circuit protective layer 470 and the subsidiary circuit protective layer 490 overlapping with the flexible circuit boards 330 on both sides, respectively, protection of the flexible circuit boards 330 may be increased (e.g., may be more reliable).

The display driver circuits 200 of the display device 70 may be disposed between the circuit protective layer 470 and the bending protective layer 450, and may be spaced apart from them in the first direction X.

In some embodiments, in the display device 70, there may be a vacant area VA between the flexible circuit boards 330 and the subsidiary circuit protective layer 490. The other elements illustrated in FIG. 12 may be the same or substantially the same as those described above, and thus, redundant description thereof may not be repeated.

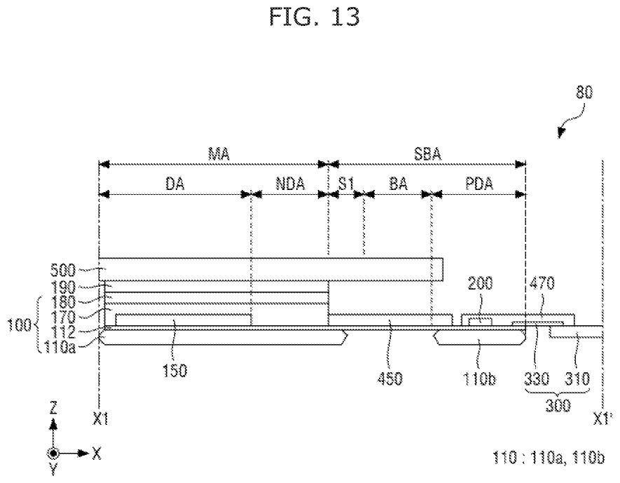

Referring to FIG. 13, a display device 80 may be different from those described above, in that in the display device 80, display driver circuits 200 are separated from a circuit board 300, and a circuit protective layer 470 completely covers the display driver circuits 200 and flexible circuit boards 330 that are spaced apart (e.g., separated) from each other. The circuit protective layer 470 of the display device 80 may be spaced apart from the bending protective layer 450.

Because the circuit protective layer 470 of the display device 80 completely covers the display driver circuits 200 and the flexible circuit boards 330 that are spaced apart from each other, adhesive properties of the circuit protective layer 470 may be further enhanced when compared to those of the display device 70. As a result, mechanical reliability of the circuit board 300 included in the display device 80 may be improved. The other elements illustrated in FIG. 13 may be the same or substantially the same as those described above, and thus, redundant description thereof may not be repeated.

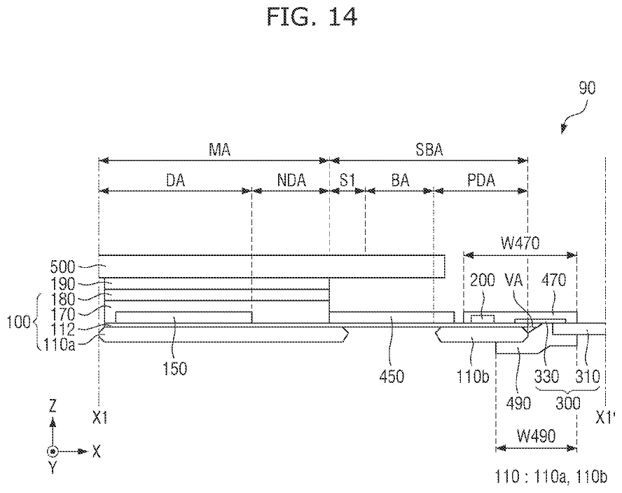

Referring to FIG. 14, a display device 90 may be different from the display device 80 described above, in that the display device 90 further includes a subsidiary circuit protective layer 490 overlapping with the circuit protective layer 470. The subsidiary circuit protective layer 490 may be positioned on the opposite side of the second substrate 112 relative to the circuit protective layer 470.

A width W490 of the subsidiary circuit protective layer 490 may be equal to or smaller than a width W470 of the circuit protective layer 470. Although the subsidiary circuit protective layer 490 covers the flexible circuit boards 330 in the example shown in the drawings, the present disclosure is not limited thereto. In other words, the subsidiary circuit protective layer 490 may have the width W490 equal to the width W470 of the circuit protective layer 470, and may be positioned to overlap with the display driver circuits 200 and the flexible circuit boards 330.

Although the circuit protective layer 470 and the subsidiary circuit protective layer 490 are both disposed in FIG. 14, the present disclosure is not limited thereto. For example, the display device 90 may not include the circuit protective layer 470, and may include the subsidiary circuit protective layer 490 under the second substrate 112. However, it should be noted that when the display device 90 includes both the circuit protective layer 470 and the subsidiary circuit protective layer 490 overlapping with the flexible circuit boards 330 on both sides, respectively, protection of the display driver circuits 200 and the flexible circuit boards 330 may be improved (e.g., may be more reliable). The other elements illustrated in FIG. 14 may be the same or substantially the same as those described above, and thus, redundant description thereof may not be repeated.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device comprising:
a first substrate comprising:
a display area; and
a non-display area surrounding the display area, and comprising a bending area and a pad area;
a display element layer on the display area of the first substrate;
a bending protective layer on the bending area of the first substrate;
a flexible circuit board on the pad area of the first substrate;
a circuit protective layer on the pad area of the first substrate, and completely covering the flexible circuit board;
a first support member under the display area of the first substrate; and
a second support member under the pad area of the first substrate, and spaced from the first support member, the second support member comprising:
a first surface in contact with the first substrate;
a second surface opposite to the first surface;
a first side surface connecting the first surface to the second surface and facing toward the first support member; and
a second side surface opposite to the first side surface,
wherein the second side surface comprises a first inclined surface connected to the second surface, and the first inclined surface of the second support member overlaps with the circuit protective layer.

2. The display device of claim 1, wherein the first surface of the second support member further comprises:
a first portion overlapping with the bending protective layer;
a second portion overlapping with the flexible circuit board and the circuit protective layer; and
a third portion overlapping with the circuit protective layer and not overlapping with the flexible circuit board, and
wherein the third portion of the second support member is between the first portion and the second portion.

3. The display device of claim 2, wherein the first portion and the third portion of the second support member are spaced from each other.

4. The display device of claim 3, wherein the second side surface of the second support member further comprises:
a second inclined surface connected to the first surface; and
a connecting surface connecting the first inclined surface to the second inclined surface, and
wherein the first inclined surface and the connecting surface form a first inclination angle therebetween, the second inclined surface and the connecting surface form a second inclination angle therebetween, and the circuit protective layer overlaps with the second inclined surface and the connection surface.

5. The display device of claim 3, wherein the circuit protective layer comprises:
an adhesive layer in direct contact with the flexible circuit board; and
a protective layer on the adhesive layer.

6. The display device of claim 5, wherein the first support member and the second support member comprise glass and a plastic, and
wherein a thickness of the first support member and the second support member is equal to or less than 200 μm.

7. The display device of claim 1, wherein the first side surface of the second support member further comprises:
a third inclined surface connected to the second surface; and
a fourth inclined surface connected to the third inclined surface and the first surface, and
wherein the bending protective layer overlaps with the third inclined surface and the fourth inclined surface.

8. The display device of claim 1, further comprising a display driver circuit on the flexible circuit board,
wherein the circuit protective layer is in contact with the display driver circuit, and
wherein the circuit protective layer completely covers the display driver circuit.

9. The display device of claim 8, further comprising a main circuit board spaced from the first substrate, and connected to the first substrate by the flexible circuit board,
wherein the circuit protective layer is in contact with the main circuit board, and partially covers the main circuit board.

10. The display device of claim 1, wherein the circuit protective layer comprises an alignment mark in a plan view, and
wherein the alignment mark overlaps with the pad area, and is located at each of two corners of the circuit protective layer.

11. The display device of claim 1, wherein the circuit protective layer comprises an alignment hole in a plan view, and
wherein the alignment hole overlaps with the pad area, and is located at each of two corners of the circuit protective layer.

12. The display device of claim 1, wherein the circuit protective layer overlaps with the display element layer when the first substrate is bent.

13. The display device of claim 1, further comprising a subsidiary circuit protective layer under the pad area of the first substrate,
wherein the subsidiary circuit protective layer is in contact with a lower portion of the second support member, and
wherein the subsidiary circuit protective layer overlaps with the first inclined surface of the second support member.

14. The display device of claim 13, wherein a width of the subsidiary circuit protective layer in a first direction is greater than a width of the flexible circuit board in the first direction.

15. The display device of claim 14, further comprising a vacant area between the flexible circuit board and the subsidiary circuit protective layer,
wherein the vacant area is surrounded by the second support member, the first substrate, the flexible circuit board, and the subsidiary circuit protective layer.

16. The display device of claim 15, further comprising a main circuit board spaced from the first substrate, and connected to the first substrate by the flexible circuit board,
wherein the subsidiary circuit protective layer is in contact with the main circuit board, and partially covers the main circuit board.

17. The display device of claim 15, wherein the subsidiary circuit protective layer overlaps with the display element layer when the first substrate is bent.

18. The display device of claim 1, further comprising a display driver circuit between the bending protective layer and the circuit protective layer,
wherein the display driver circuit is spaced from the bending protective layer and the circuit protective layer.

19. The display device of claim 1, further comprising a display driver circuit on the pad area of the first substrate, and spaced from the bending protective layer and the circuit protective layer therebetween,
wherein the circuit protective layer completely covers the display driver circuit and the flexible circuit board.

20. A display device comprising:
a first substrate comprising:
a display area; and
a non-display area surrounding the display area, and comprising a bending area and a pad area;
a display element layer on the display area of the first substrate;
a bending protective layer on the bending area of the first substrate;
a flexible circuit board on the pad area of the first substrate;
a first support member under the display area of the first substrate;
a second support member under the pad area of the first substrate, and spaced from the first support member; and
a subsidiary circuit protective layer under the pad area of the first substrate, and in contact with the second support member under the second support member,
wherein the second support member comprises:
a first surface in contact with the first substrate;
a second surface opposite to the first surface;
a first side surface connecting the first surface to the second surface, and facing toward the first support member; and
a second side surface opposite to the first side surface, and
wherein the second side surface comprises a first inclined surface connected to the second surface, and the first inclined surface of the second support member overlaps with the subsidiary circuit protective layer.
